(19) United States
(12) Patent Application Publication
(10) Pub. No.: US 2024/0254030 A1
(43) Pub. Date: Aug. 1, 2024

(54) MANUFACTURING METHOD FOR HIGH-QUALITY QUARTZ CRUCIBLE

(71) Applicant: JINZHOU YOUXIN QUARTZ TECHNOLOGY CO., LTD, Jinzhou (CN)

(72) Inventors: Man CHEN, Jinzhou (CN); Zonghui LI, Jinzhou (CN); Jian ZHU, Jinzhou (CN); Ye WANG, Jinzhou (CN); Zhen WANG, Jinzhou (CN); Zhiqiang ZHANG, Jinzhou (CN)

(73) Assignee: JINZHOU YOUXIN QUARTZ TECHNOLOGY CO., LTD, Jinzhou (CN)

(21) Appl. No.: 18/631,507

(22) Filed: Apr. 10, 2024

Related U.S. Application Data
(63) Continuation of application No. PCT/CN2022/119998, filed on Sep. 20, 2022.

(30) Foreign Application Priority Data
Mar. 25, 2022 (CN) 202210306859.X

(51) Int. Cl. C03B 19/06; C30B 15/10; C30B 29/06

(52) U.S. Cl. CPC C03B 19/066; C30B 15/10; C30B 29/06

(57) ABSTRACT

A manufacturing method for high-quality quartz crucible uses a vacuum arc method to melt, the positioning of the graphite electrode and dwell time at each position meet following requirements in which: taking a position of an upper end surface of a mold opening as a zero point, an end of the graphite electrode is marked as + when above the zero point, marked as − when below the zero point; a starting position of the graphite electrode is +0.10˜0.30 times an outer diameter of the crucible, dwell time ≥2 minutes, then the position is descended sequentially in accordance with a stepwise positioning method, staying for a period of time every time descending to a position, the graphite electrode continuously releases a high-temperature arc to melt crucible blank during a corresponding period of time at a corresponding position, and reaches a bottom polishing position after moving at least 3 times.

### CROSS-REFERENCE TO RELATED APPLICATIONS

This application is a continuation of International Application No. PCT/CN2022/119998, filed on Sep. 20, 2022, which claims priority to Chinese Patent Application No. 202210306859.X, filed on Mar. 25, 2022. The disclosures of the above-mentioned applications are hereby incorporated by reference in their entireties.

### TECHNICAL FIELD

The present application relates to the field of single crystal silicon production, and in particular, to a manufacturing method for a quartz crucible used when manufacturing silicon single crystal by the Czochralski method (Czochralski, hereinafter referred to as the CZ pulling method).

### BACKGROUND

Silicon single crystal is one of the most important raw materials for making silicon-based semiconductor materials and solar cells. Silicon single crystal is mainly produced by the CZ pulling method. In the CZ pulling method, the polycrystalline silicon raw material is placed in a quartz crucible to heat the molten silicon melt. A pull rod drives the seed crystal down to contact the silicon melt, and then slowly pulls the seed crystal upward to form a silicon single crystal rod. The quartz crucibles generally have a double-layer structure. The inner wall is a transparent layer without bubbles, and the outer wall is an non-transparent layer with more bubbles. Because the inner wall is in contact with the silicon melt, if there are bubbles in the inner wall at a high temperature, the bubbles will burst due to erosion by the silicon melt. If any broken fragment is dissolved in the silicon melt, it will affect the yield and quality of the silicon single crystal. The outer wall needs to scatter the heat from the heater evenly, so a specified number and size of bubbles are needed to evenly heat the silicon melt. As the only material in contact with silicon solution, the quality of quartz crucibles has a great influence on the quality of silicon single crystal. For example, the content of bubbles in the inner wall of the quartz crucible, the purity of the quartz crucible, the high temperature deformation resistance of the quartz crucible, etc.

Quartz crucibles are generally manufactured using a vacuum arc method. When using this method, the high-purity quartz sand raw material is poured into a graphite mold or a metal mold, and the quartz sand raw material is evenly formed on the inner surface of the mold through a forming device, and then quartz sand is melt at a temperature above 3000° C. using high-temperature arcs (typically with three graphite electrodes in a three-phase arc furnace), and finally formed into a quartz (glass) crucible by rapid cooling. In the process of producing the quartz crucible by vacuum arc method, the temperature of the arc has a great influence on the quality of the quartz crucible, such as the content of bubbles in the inner wall of the crucible, the purity, the high temperature deformation resistance, vitrification degree, etc. Therefore, how to optimize the control of the arc is very important.

In the control of arc temperature, the positioning of the graphite electrode (the position of the electrode end relative to the upper end of the mold opening) will significantly improve production quality of the quartz crucible under the condition that the current is constant (with unchanged power equipment). However, at present, fixed positioning melting method is generally used for electrode positioning in the process of manufacturing quartz crucibles (referred to as fixed positioning method or Fixed Type Method, FT method for short in this application). The positioning of the graphite electrode in the FT method is fixed, and only the consumption of the graphite electrode is periodically compensated by descending (descending a certain distance to compensate for the consumption of the electrode). Currently, the existing manufacturing method only improves the production quality of the quartz crucible by adjusting the current magnitude. However, in actual production, it is found that the improvement of the quality of quartz crucibles only by adjusting the current magnitude is very limited, and once the production equipment is built, the amount of current that its component hardware can carry is limited, so it is difficult to improve the production quality of the crucible by replacing to large currents, and the cost of changing the hardware and rebuilding the equipment is also prohibitive. As a result, a manufacturing method to improve the quality of quartz crucibles remains a technical problem that researchers in the industry urgently need to solve.

### SUMMARY

A manufacturing method for a high-quality quartz crucible is provided in the present application in view of the above-mentioned shortcomings and deficiencies of the prior art. The method mainly produces a high-quality quartz crucible by controlling the positioning of the graphite electrode and time allocation of each position, including improving the high-temperature resistance strength of the crucible, improving the purity of the transparent layer, reducing bubbles in the inner wall of the crucible, etc. It solves the technical problems caused by the prior art to improve the quality of the crucible by changing current under fixed positioning.

In order to achieve the above objectives, the main technical solution utilized in the present application includes the following.

In a first aspect, a manufacturing method for a high-quality quartz crucible is provided in the present application. The manufacturing method uses a vacuum arc method and includes following steps.

Pouring high-purity quartz sand raw material into a crucible mold, using a molding device to evenly form the quartz sand raw material on an inner surface of the mold to form a crucible blank; moving the crucible mold as a whole into an arc melting furnace, melting the quartz sand by releasing high-temperature arc through a graphite electrode, and finally, rapidly cooling to form a quartz crucible blank; wherein in the process of using the graphite electrode to release high-temperature arc, control a position of the graphite electrode in the height direction and the dwell time at each position to meet following requirements.

Taking a position of an upper end surface of a mold opening as a zero point, the end of the graphite electrode is marked as + when above the zero point, marked as − when below the zero point; during melting process, a starting position of the graphite electrode is + (0.10˜0.30) times an outer diameter of the crucible, dwell time ≥2 minutes, then the position is descended sequentially in accordance with a ladder positioning method, staying for a period of time every time descending to a position, the graphite electrode continuously releases a high-temperature arc to melt the crucible blank during a corresponding period of time at a corresponding position, and reaches a bottom polishing position after moving at least 3 times; the bottom polishing position is the lowest position that the graphite electrode reaches and enters an interior of the crucible blank (the position is negative), 300-550 mm away from a bottom of the crucible; at the bottom polishing position, the graphite electrode stays for a predetermined time to perform high-temperature polishing and volatile impurity removal to the bottom of the crucible.

After leaving from the bottom polishing position, the graphite electrode ascends again to the finishing position, which is + (0.05˜0.07) times the outer diameter of the crucible, at this position, high-temperature polishing and volatile impurity removal are conducted to an upper part of an inner wall of the quartz crucible.

When the number of moves from the starting position to the bottom polishing position is 3 times, the height difference between two adjacent positions is ≥50 mm; and when the number of moves from the starting position to the bottom polishing position is greater than 3 times, then there is no need for the height difference between every two steps to be ≥50 mm.

According to a preferred embodiment of the present application, during the entire melting process, the position of the graphite electrode includes a starting position, a second position, a third position, a fourth position, a fifth position, a bottom polishing position and a finishing position, where from the starting position to the bottom polishing position is a stepwise descent and stays for a period of time at each position.

According to a preferred embodiment of the present application, the dwell time allocation for the graphite electrode at each position is as follows: a sum of the dwell time at the starting position, the second position, and the third position is 0.4-0.5 t, the dwell time at the fourth position is 0.1-0.2 t, the dwell time at the fifth position is 0.1 t, the dwell time at the bottom polishing position is 0.2-0.3 t, and the dwell time at the finishing position is 0.1 t; t is a total melting time of a target quartz crucible.

According to a preferred embodiment of the present application, according to quartz crucibles of different specifications, the dwell time allocation for the graphite electrode at each position is as follows: quartz crucible with an outer diameter of 24 inches: the sum of the dwell time at the starting position, the second position and the third position is 0.4 t, the dwell time at the fourth position is 0.2 t, the dwell time at the fifth position is 0.1 t, the dwell time at the bottom polishing position is 0.2 t; the dwell time at the finishing position is 0.1 t; and the total melting time is 14-16 minutes, preferably 15 minutes.

Quartz crucible with an outer diameter of 26 inches: the sum of the dwell time at the starting position, the second position and the third position is 0.45 t, the dwell time at the fourth position is 0.15 t, the dwell time at the fifth position is 0.1 t, the dwell time at the bottom polishing position is 0.2 t; the dwell time at the finishing position is 0.1 t; and the total melting time is 17-19 minutes, preferably 18 minutes.

Quartz crucible with an outer diameter of 28 inches: the sum of the dwell time at the starting position, the second position and the third position is 0.45 t, the dwell time at the fourth position is 0.1 t, the dwell time at the fifth position is 0.1 t, the dwell time at the bottom polishing position is 0.25 t; the dwell time at the finishing position is 0.1 t; and the total melting time is 22-26 minutes, preferably 24 minutes.

Quartz crucible with an outer diameter of 32 inches: the sum of the dwell time at the starting position, the second position and the third position is 0.4 t, the dwell time at the fourth position is 0.1 t, the dwell time at the fifth position is 0.1 t, the dwell time at the bottom polishing position is 0.3 t; the dwell time at the finishing position is 0.1 t; and the total melting time is 28-32 minutes, preferably 30 minutes.

According to a preferred embodiment of the present application, during graphite electrode positioning process, positioning accuracy of the graphite electrode at each position is ±5 mm.

According to a preferred embodiment of the present application, during the entire melting process, vacuum pressure is controlled at −0.093 MPa˜−0.1 MPa; power of the graphite electrode is 500-2000 kW.

According to a preferred embodiment of the present application, when melting a quartz crucible with an outer diameter of 24 inches, the power of the graphite electrode is 750-850 kW; when melting a quartz crucible with an outer diameter of 26 inches, the power of the graphite electrode is 850-950 kW; when melting a quartz crucible with an outer diameter of 28 inches, the power of the graphite electrode is 1000-1100 kW; when melting a quartz crucible with an outer diameter of 32 inches, the power of the graphite electrode is 1300-1400 kW.

According to a preferred embodiment of the present application, during graphite electrode positioning process, at the end of melting at each position, the graphite electrode is subjected to air blowing for dust removal, and volatile matter deposited on a surface of the graphite electrode is blown away.

According to a preferred embodiment of the present application, a height difference between the bottom polishing position (or referred to a bottoming position, which is also the lowest position reached by the graphite electrode) and the fifth position is more than 100 mm.

According to a preferred embodiment of the present application, the produced quartz crucible blank is cut, inspected, cleaned, dried, packaged and stored in sequence.

According to a preferred embodiment of the present application, the positioning of the graphite electrode of the present application is programmably controlled by the PLC module.

In a second aspect, the present application provides a high-quality quartz crucible, which is manufactured using the manufacturing method of any of the above embodiments.

By accurately controlling the starting position of the graphite electrode and followed by descending to the bottom polishing position (the position is negative) in sequence according to the stepwise positioning method, and in conjunction with the dwell time at each position (the time of releasing the high-temperature arc), the quality of the crucible can be greatly improved, including reducing bubbles in the inner wall of the quartz crucible, improving the purity of the transparent layer of the crucible, enhancing high temperature deformation resistance, reducing the sagging rate of the crucible wall during the crystal pulling process, etc., providing support for improving the yield and production quality of silicon single crystals produced by the CZ pulling method.

Compared with the fixed positioning method, the present application does not simply improve the quality of the crucible by increasing the working current of the graphite electrode.

The hardware of the quartz crucible production equipment does not need to be changed. It has a greater flexibility margin and is suitable for producing crucible with various specifications. From the starting position to the bottom polishing position, the graphite electrode is lowered at least 3 times to reach the inside of the crucible and close to the bottom of the crucible blank. During the entire melting process, the graphite electrode gradually approaches the inner center of the crucible blank, in conjunction with the allocation of dwell time of the electrode at each position ensures that the heat is evenly distributed to the inner surfaces of the crucible blank, including the straight wall surface, arc-shaped transition parts and bottom, etc., while the local area is subjected to extremely high temperature concentrated treatment, so that the impurities contained in the inner surface of the crucible are evaporated at high temperature, the purity of the transparent layer of the crucible is improved, thus ensures the quality of silicon single crystal. After the graphite electrode reaches the lowest position to perform high-temperature polishing on the bottom of the crucible, then it is raised above the crucible mold to the finishing position, which is used to process the upper part of the crucible opening to remove impurities that have volatilized and then deposited on the upper part of the inner wall of the crucible. By comparison, the present application can effectively reduce the impurity content in the inner wall surface of the crucible, improve the high-temperature deformation resistance of the crucible, and reduce the sagging rate of the crucible wall surface during the crystal pulling process.

### BRIEF DESCRIPTION OF THE DRAWINGS

FIG. 1 is a schematic structural diagram of a quartz crucible.

FIG. 2 is a schematic diagram of producing quartz crucible using high-temperature arc melting.

FIG. 3 is a schematic diagram of the starting position and zero point position of the graphite electrode during the process of producing quartz crucible using high-temperature arc melting.

FIG. 4 illustrates the graphite electrode positioning and the time allocation at each position when producing a 26 inch quartz crucible in Example 1.

FIG. 5 illustrates the positioning of the graphite electrode positioning and the time distribution at each position when producing a 26 inch quartz crucible in Example 2.

FIG. 6 illustrates the positioning of the graphite electrode and the time distribution at each position when producing a 26 inch quartz crucible in Example 3.

FIG. 7 illustrates the positioning of the graphite electrode and the time distribution at each position when producing a 24 inch quartz crucible in Example 4.

FIG. 8 illustrates the positioning of the graphite electrode and the time distribution at each position when producing a 28 inch quartz crucible in Example 5.

FIG. 9 illustrates the positioning of the graphite electrode and the time distribution at each position when producing a 32 inch quartz crucible in Example 6.

FIG. 10 is a schematic diagram of sagging condition of the end surface of the quartz crucible after being used to produce silicon single crystal by the CZ method.

### DETAILED DESCRIPTION OF THE EMBODIMENTS

In order to better explain the present application and facilitate understanding, the present application will be described in detail below through specific embodiments in conjunction with the accompanying drawings.

FIG. 1 is a schematic diagram of a quartz crucible, which includes an inner transparent layer 1 and an outer non-transparent layer 2. The transparent layer 1 is in direct contact with the silicon melt. The transparent layer 1 includes a straight wall surface H, an arc transition surface L, and a bottom surface W.

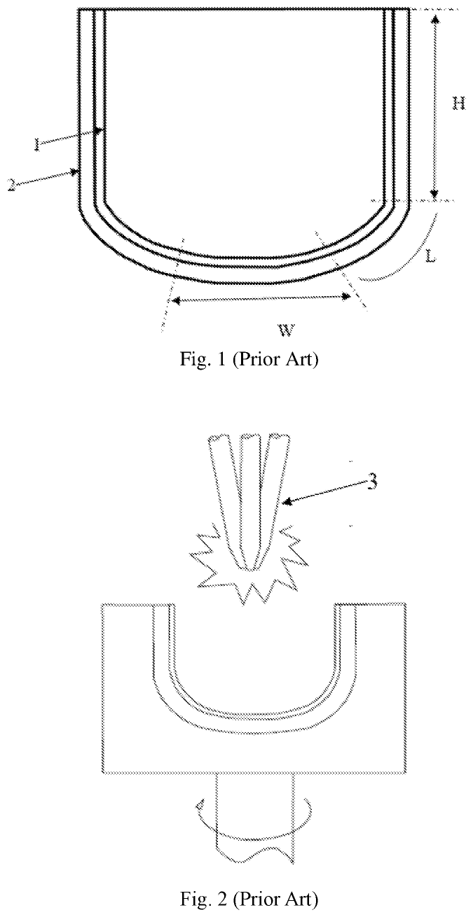

As shown in FIG. 2, it is a schematic diagram of producing quartz crucible using high-temperature arc melting in the prior art. In the prior art, the graphite electrode 3 enters the inside of the crucible mold, and the graphite electrode 3 releases a high-temperature arc to melt the quartz raw material. As the graphite electrode 3 consumes during the process of releasing high-temperature arc, the graphite electrode 3 continues to move downward, but the distance between the lower end of the graphite electrode and the bottom of the crucible remains unchanged during the entire melting process. This technology can be defined as fixed positioning method in the present application. Fixed positioning means that the distance between the lower end of the graphite electrode to the upper end surface of the mold opening (zero point) remains unchanged.

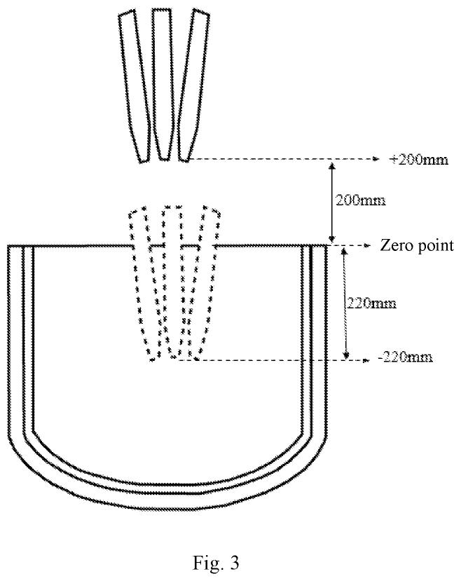

As shown in FIG. 3, based on the prior art, the heat distribution during the melting process of quartz crucible is improved by changing the position of the lower end of the graphite electrode in the present application, specifically, changing the distance between the lower end of the graphite electrode relative to the upper end surface of the mold opening in a stepwise manner (hereinafter referred to the position of the graphite electrode). In the process of changing the position of the graphite electrode, the present application adopts a stepwise descending mode, which is programmed and controlled by the PLC module. When the graphite electrode reaches the inside of the crucible to perform high-temperature polishing to the bottom of the crucible, this position is called the bottom polishing position. The stepwise descending includes two meanings. The first one is that the position of the graphite electrode is continuously descending. The second one is that it stays for a period of time at each position, during this period, the graphite electrode continuously releases high-temperature arc to heat and melt the crucible blank and remove impurities by high-temperature volatilization. When high-temperature arc is released, the temperature can reach 3000-3600 degrees. Some metal impurities will volatilize at this temperature, thereby purifying the transparent layer 1 of the crucible and ensuring the production quality of silicon single crystal. After the graphite electrode is finished working at the bottom polishing position, it is then raised above the mold opening to volatilize the impurities deposited on the upper part of the inner wall of the crucible at high temperature (during bottom polishing, some impurities will be volatilized and redeposited at a lower temperature location). After the melting is completed, it is cooled to obtain the quartz crucible blank, which is then cut, inspected, cleaned, dried, packaged and stored.

As shown in FIG. 3, with the upper end surface of the mold opening as the zero point, the end of the graphite electrode is marked as + when above the zero point, and marked as − when below the zero point. Specifically, the solution of the present application is as follows.

During the melting process, the starting position of the graphite electrode is + (0.10˜0.30) times the outer diameter of the crucible, and the dwell time is ≥2 minutes. After that, the graphite electrode descends in sequence according to the stepwise positioning method, and stays for a period of time every time descending to a position. The graphite electrode continuously releases a high-temperature arc to melt the crucible blank during the corresponding period of time at the corresponding position, and reaches the bottom polishing position after moving at least 3 times; the bottom polishing position is the lowest position reached by the graphite electrode and enters the inside of the crucible blank (the position is negative), 300-550 mm away from the bottom of the crucible; at the bottom polishing position, the graphite electrode stays for a predetermined time to perform high-temperature polishing and volatile impurity removal to the bottom of the crucible.

After the graphite electrode leaves from the bottom polishing position, it ascends again to the finishing position, which is + (0.05˜0.07) times the outer diameter of the crucible. At this position, high-temperature polishing and volatile impurity removal are conducted on the upper part of the inner wall of the quartz crucible.

During the entire melting process, the position of the graphite electrode includes the starting position, the second position, the third position, the fourth position, the fifth position, the bottom polishing position and the finishing position, where from the starting position to the bottom polishing position is stepwise descending and staying at each position for a period of time; the positioning accuracy of the graphite electrode at each position is ±5 mm.

Preferably, the dwell time allocation for the graphite electrode at each position is as follows: the sum of the dwell time at the starting position, the second position, and the third position is 0.4-0.5 t, the dwell time at the fourth position is 0.1-0.2 t, the dwell time at the fifth position is 0.1 t, the dwell time at the bottom polishing position is 0.2-0.3 t, and the dwell time at the finishing position is 0.1 t; t is the total melting time of the target quartz crucible.

Further, according to quartz crucibles with different specifications, the dwell time allocation for the graphite electrode at each position is as follows: quartz crucible with an outer diameter of 24 inches: the sum of the dwell time at the starting position, the second position and the third position is 0.4 t, the dwell time at the fourth position is 0.2 t, the dwell time at the fifth position is 0.1 t, the dwell time at the bottom polishing position is 0.2 t; the dwell time at the finishing position is 0.1 t; and the total melting time is 14-16 minutes, preferably 15 minutes.

Quartz crucible with an outer diameter of 26 inches: the sum of the dwell time at the starting position, the second position and the third position is 0.45 t, the dwell time at the fourth position is 0.15 t, the dwell time at the fifth position is 0.1 t, the dwell time at the bottom polishing position is 0.2 t; the dwell time at the finishing position is 0.1 t; and the total melting time is 17-19 minutes, preferably 18 minutes.

Quartz crucible with an outer diameter of 28 inches: the sum of the dwell time at the starting position, the second position and the third position is 0.45 t, the dwell time at the fourth position is 0.1 t, the dwell time at the fifth position is 0.1 t, the dwell time at the bottom polishing position is 0.25 t; the dwell time at the finishing position is 0.1 t; and the total melting time is 22-26 minutes, preferably 24 minutes.

Quartz crucible with an outer diameter of 32 inches: the sum of the dwell time at the starting position, the second position and the third position is 0.4 t, the dwell time at the fourth position is 0.1 t, the dwell time at the fifth position is 0.1 t, the dwell time at the bottom polishing position is 0.3 t; the dwell time at the finishing position is 0.1 t; and the total melting time is 28-32 minutes, preferably 30 minutes.

Preferably, during the entire melting process, the vacuum pressure is controlled at −0.093 MPa˜−0.1 MPa; the power of the graphite electrode is 500-2000 kW.

Preferably, when melting the quartz crucible with an outer diameter of 24 inches, the power of the graphite electrode is 750-850 kW; when melting the quartz crucible with an outer diameter of 26 inches, the power of the graphite electrode is 850-950 kW; when melting the quartz crucible with an outer diameter of 28 inches, the power of the graphite electrode is 1000-1100 kW; when melting the quartz crucible with an outer diameter of 32 inches, the power of the graphite electrode is 1300-1400 kW.

Preferably, during the graphite electrode positioning process, at the end of melting at each position, the graphite electrode is subjected to air blowing for dust removal, and the volatile matter deposited on the surface of the graphite electrode is blown away.

Preferably, the height difference between the bottom polishing position (or referred to the bottoming position, which is also the lowest position reached by the graphite electrode) and the fifth position is more than 100 mm.

The features and effects of the present application will be described below in conjunction with preferred embodiments of the present application. Unless otherwise specified, the raw material in the following embodiments are all from the same batch of quartz raw material, and the purity of high-purity quartz sand is ≥99.99%.

### Example 1

A manufacturing method for high-quality quartz crucible is provided in this embodiment, which is used to manufacture a quartz crucible with an outer diameter of 26 inches, using the vacuum arc method. The steps are as follows.
(1) Evenly distributing high-purity quartz sand powder in the crucible mold and forming it.
(2) Moving the formed mold into the arc melting furnace.
(3) Setting the position of the upper end face of the mold opening as the zero point, PLC programmably controlling the position of the graphite electrode as shown in FIG. 4, and performing melting to the quartz crucible. In the figure, the graphite electrode works in a total of 7 positions. It stays at the starting position for 3 minutes, at the second position for 3 minutes, at the third position for 3 minutes, at the fourth position for 1.8 minutes, at the fifth position for 1.8 minutes, at the bottom polishing position for 3.6 minutes (310 mm away from the bottom of the crucible), and at the finishing position for 1.8 minutes.

During the melting process, the power of the graphite electrode is controlled at 900 kW, the accuracy at each position is ±5 mm, and the vacuum pressure is controlled at −0.093 MPa˜−0.1 MPa. At the end of the melting step at each position, the graphite electrode is subjected to air blowing for dust removal, to blow away the deposited volatiles.
(4) After the melting is completed, the quartz crucible being cooled and removed from the furnace to complete the production of the quartz crucible blank.
(5) The produced quartz crucible blank being cut, inspected, cleaned, dried, packaged and stored in sequence.

### Example 2

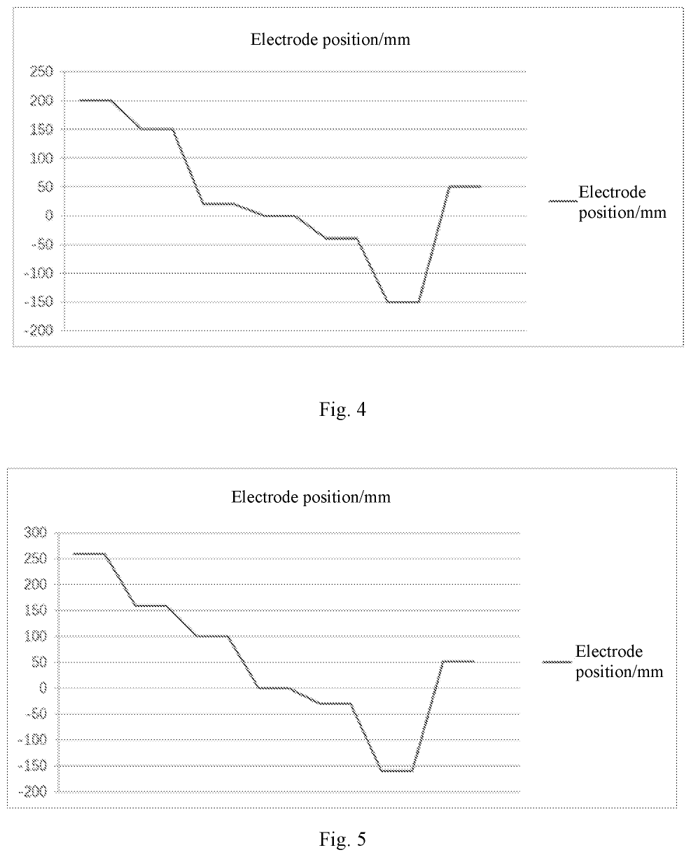

This example is based on Example 1. The positioning of the graphite electrode is controlled by PLC program as shown in FIG. 5, to perform melting to the quartz crucible. In the figure, the graphite electrode works in a total of 7 positions. It stays at the starting position for 3 minutes, at the second position for 2 minutes, at the third position for 3.1 minutes, at the fourth position for 2.7 minutes, at the fifth position for 1.8 minutes, at the bottom polishing position for 3.6 minutes (300 mm away from the bottom of the crucible), and at the finishing position for 1.8 minutes.

### Example 3

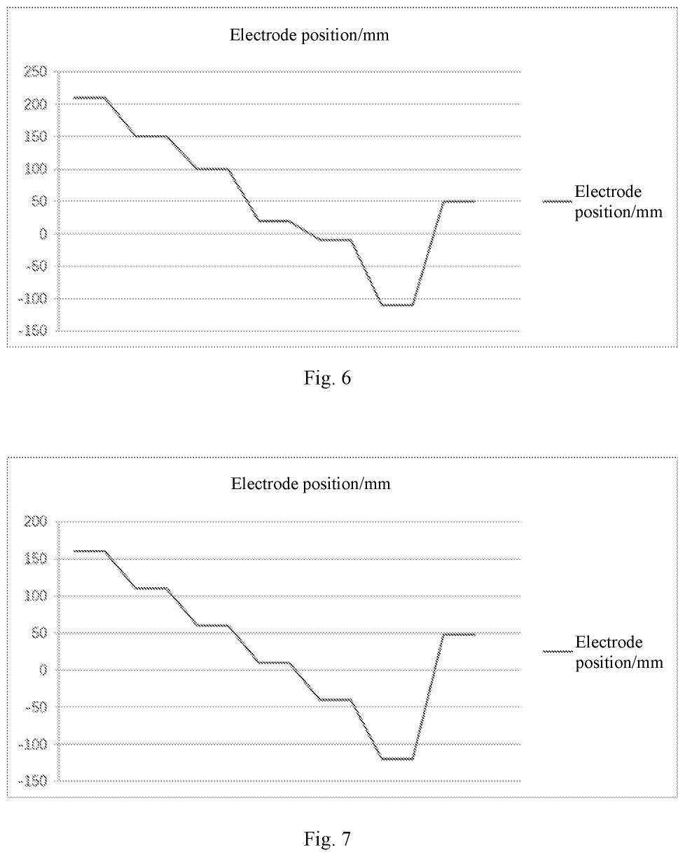

This example is based on example 1. The positioning of the graphite electrode is controlled by PLC program as shown in FIG. 6, to perform melting to the quartz crucible. In the picture, the graphite electrode works in a total of 7 positions. It stays at the starting position for 3 minutes, at the second position for 2 minutes, at the third position for 2.2 minutes, at the fourth position for 3.6 minutes, at the fifth position for 1.8 minutes, and at the bottom polishing position for 3.6 minutes (350 mm away from the bottom of the crucible), and at the finishing position for 1.8 minutes.

### Comparative Example 1

In this example, a fixed positioning method is used to manufacture a quartz crucible with an outer diameter of 26 inches. The steps are as follows.
(1) Evenly distributing high-purity quartz sand powder in the crucible mold and forming it; the quartz raw material is the same batch of the raw material as in Example 1.
(2) Moving the formed mold into the arc melting furnace.
(3) Positioning the graphite electrode at −150 mm, the power of the graphite electrode being 900 kW, the vacuum pressure being controlled at −0.093 MPa˜−0.1 MPa, performing air blow to the graphite electrode to remove dust every 3 minutes to blow away the deposited volatiles. As the graphite electrode is consumed, adaptively moving the graphite electrode downward, so that the distance from the lower end of the graphite electrode to the upper end face of the mold opening is maintained at −150 mm (310 mm away from the bottom of the crucible).
(4) After the melting is completed, the quartz crucible being cooled and removed from the furnace to complete the production of the quartz crucible blank.
(5) The produced quartz crucible blank being cut, inspected, cleaned, dried, packaged and stored in sequence.

### Example 4

A manufacturing method for high-quality quartz crucible is provided in this embodiment, which is used to manufacture a quartz crucible with an outer diameter of 24 inches, using the vacuum arc method. The steps are as follows.
(1) Evenly distributing high-purity quartz sand powder in the crucible mold and forming it.
(2) Moving the formed mold into the arc melting furnace.
(3) Setting the position of the upper end face of the mold opening as the zero point, PLC programmably controlling the position of the graphite electrode as shown in FIG. 7, and performing melting to the quartz crucible. In the figure, the graphite electrode works in a total of 7 positions. It stays at the starting position for 2 minutes, at the second position for 2 minutes, at the third position for 2 minutes, at the fourth position for 3 minutes, at the fifth position for 1.5 minutes, at the bottom polishing position for 3 minutes (340 mm away from the bottom of the crucible), and at the finishing position for 1.5 minutes.

During the melting process, the power of the graphite electrode is controlled at 800 kW, the accuracy at each position is ±5 mm, and the vacuum pressure is controlled at −0.093 MPa˜−0.1 MPa. At the end of the melting step at each position, the graphite electrode is subjected to air blowing for dust removal, to blow away the deposited volatiles.
(4) After the melting is completed, the quartz crucible being cooled and removed from the furnace to complete the production of the quartz crucible blank.
(5) The produced quartz crucible blank being cut, inspected, cleaned, dried, packaged and stored in sequence.

### Example 5

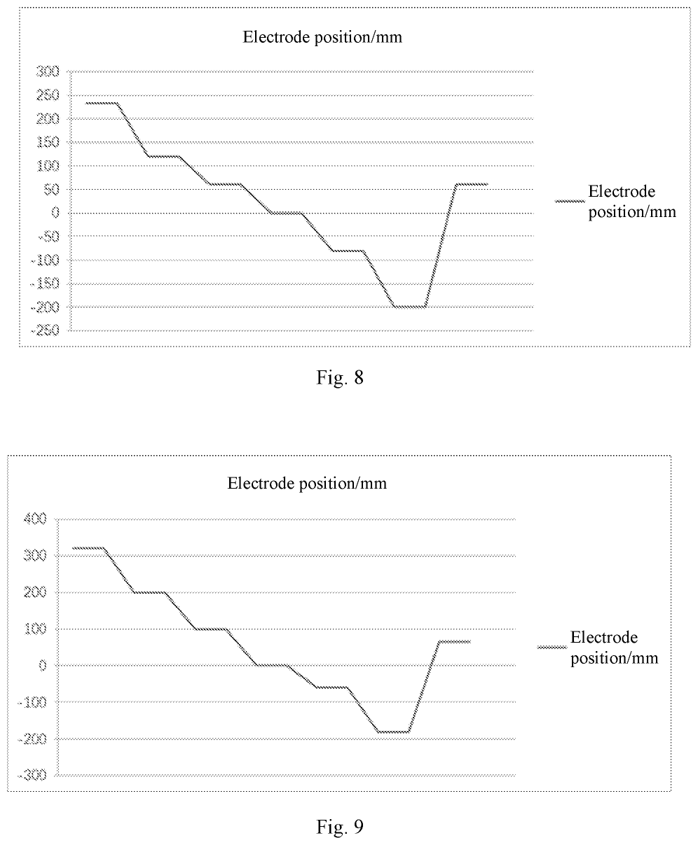

A manufacturing method for high-quality quartz crucible is provided in this embodiment, which is used to manufacture a quartz crucible with an outer diameter of 28 inches, using the vacuum arc method. The steps are as follows.
(1) Evenly distributing high-purity quartz sand powder in the crucible mold and forming it.
(2) Moving the formed mold into the arc melting furnace.
(3) Setting the position of the upper end face of the mold opening as the zero point, PLC programmably controlling the position of the graphite electrode as shown in FIG. 8, and performing melting to the quartz crucible. In the figure, the graphite electrode works in a total of 7 positions. It stays at the starting position for 3.6 minutes, at the second position for 3.6 minutes, at the third position for 3.6 minutes, at the fourth position for 2.4 minutes, at the fifth position for 2.4 minutes, at the bottom polishing position for 6 minutes (420 mm away from the bottom of the crucible), and at the finishing position for 2.4 minutes.

The power of the graphite electrode is controlled at 1050 kW, the accuracy at each position is 5 mm, and the vacuum pressure is controlled at −0.093 MPa˜−0.1 MPa. At the end of the melting step at each position, the graphite electrode is subjected to air blowing for dust removal, to blow away the deposited volatiles.
(4) After the melting is completed, the quartz crucible being cooled and removed from the furnace to complete the production of the quartz crucible blank.
(5) The produced quartz crucible blank being cut, inspected, cleaned, dried, packaged and stored in sequence.

### Example 6

A manufacturing method for high-quality quartz crucible is provided in this embodiment, which is used to manufacture a quartz crucible with an outer diameter of 32 inches, using the vacuum arc method. The steps are as follows.
(1) Evenly distributing high-purity quartz sand powder in the crucible mold and forming it.
(2) Moving the formed mold into the arc melting furnace.
(3) Setting the position of the upper end face of the mold opening as the zero point, PLC programmably controlling the position of the graphite electrode as shown in FIG. 9, and performing melting to the quartz crucible. In the figure, the graphite electrode works in a total of 7 positions. It stays at the starting position for 4 minutes, at the second position for 4 minutes, at the third position for 4 minutes, at the fourth position for 3 minutes, at the fifth position for 3 minutes, at the bottom polishing position for 9 minutes (500 mm away from the bottom of the crucible), and at the finishing position for 3 minutes.

During the melting process, the power of the graphite electrode is controlled at 1400 kW, the accuracy at each position is ±5 mm, and the vacuum pressure is controlled at −0.093 MPa˜−0.1 MPa. At the end of the melting step at each position, the graphite electrode is subjected to air blowing for dust removal, to blow away the deposited volatiles.
(4) After the melting is completed, the quartz crucible being cooled and removed from the furnace to complete the production of the quartz crucible blank.
(5) The produced quartz crucible blank being cut, inspected, cleaned, dried, packaged and stored in sequence.

Compare the performance of the quartz crucibles prepared in the embodiments, including by the CZ method, after producing a silicon single crystal (taking 100 hours), the sagging condition of the quartz crucible and the comparison of the content of the impurity elements in the transparent layer of the quartz crucible.

Take the inner transparent layer 1 of the quartz crucible of Examples 1-6 and Comparative Example 1, and use the atomic absorption method to detect the content of the innermost impurity elements, as shown in the following table.

Content of Impurity Element ppm

| | Ca | K | Na | Li | B | Al | Fe | Cu |
|---|---|---|---|---|---|---|---|---|
| Example 1 | 0.5 | 0.6 | 0.5 | 0.9 | 0.1 | 0.8 | 0.4 | 0.05 |
| Comparative | 0.9 | 0.8 | 1.0 | 1.1 | 0.7 | 1.8 | 0.8 | 0.1 |
| Example 1 | | | | | | | | |
| Example 2 | 0.4 | 0.4 | 0.7 | 0.8 | 0.2 | 0.9 | 0.3 | 0.04 |
| Example 3 | 0.4 | 0.5 | 0.8 | 0.7 | 0.2 | 0.8 | 0.2 | 0.06 |
| Example 4 | 0.6 | 0.3 | 0.9 | 0.8 | 0.3 | 0.7 | 0.2 | 0.05 |
| Example 5 | 0.7 | 0.4 | 0.5 | 0.6 | 0.2 | 0.6 | 0.4 | 0.08 |
| Example 6 | 0.5 | 0.6 | 0.5 | 0.8 | 0.1 | 0.7 | 0.4 | 0.05 |

It can be seen from the above comparison that the content of the surface impurity of the inner transparent layer 1 of the quartz crucible prepared in Examples 1-6 of the present application is lower and purer, which reduces the amount of impurities introduced during the crystal pulling process to produce silicon single crystal to ensure the production quality of the silicon single crystal. In addition, the quartz glass crucibles of Examples 1-6 are inspected and found to have no cracks or pits on the surface, and no bubbles or protruding spots by visually observing.

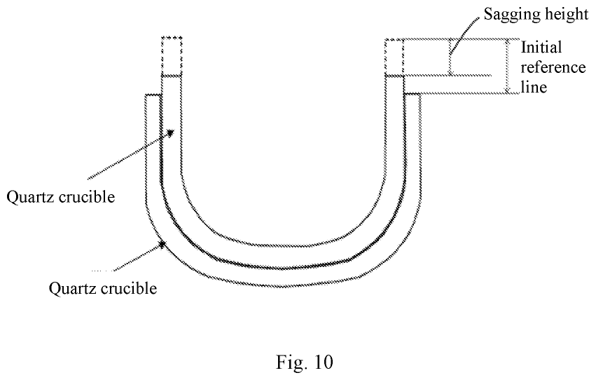

As shown in FIG. 10, after a quartz crucible is used to produce single crystal silicon using the CZ method, sagging inevitably occurs due to high-temperature melting. During the production process, the quartz crucible is positioned inside the graphite crucible, and the quartz crucible contains pure silicon melt. After producing a silicon single crystal, the sagging height of the quartz crucible in Example 1 is 3.6 mm, and that in Comparative Example 1 is 8.8 mm. This shows that the quartz crucible prepared in Comparative Example 1 has poor high-temperature deformation resistance, while the solution provided by the present application can improve this issue.

Finally, it should be noted that the above embodiments are only used to illustrate the technical solution of the present application, but not to limit it. Although the present application has been described in detail with reference to the foregoing embodiments, those of ordinary skill in the art should understand that, the technical solutions described in the foregoing embodiments can still be modified, or some or all of the technical features can be equivalently substituted; and these modifications or substitutions do not make the essence of the corresponding technical solutions deviate from the scope of the technical solutions of the embodiments in the present application.

What is claimed is:

1. A manufacturing method for high-quality quartz crucible, the manufacturing method using vacuum arc method and comprising following steps:
pouring high-purity quartz sand raw material into a crucible mold, using a forming device to evenly mold the quartz sand raw material on an inner surface of a mold to form a crucible blank, moving the crucible mold as a whole into an arc melting furnace, melting the quartz sand by releasing high-temperature arc through a graphite electrode, and finally, rapidly cooling to form a quartz crucible blank; wherein in process of using the graphite electrode to release high-temperature arc, control positioning of the graphite electrode in a height direction and dwell time at each position to meet following requirements in which:
taking a position of an upper end surface of a mold opening as a zero point, an end of the graphite electrode is marked as + when above the zero point, marked as − when below the zero point; during melting process, a starting position of the graphite electrode is +0.10˜0.30 times an outer diameter of the crucible, dwell time ≥2 minutes, then the position is descended sequentially in accordance with a stepwise positioning method, staying for a period of time every time descending to a position, the graphite electrode continuously releases a high-temperature arc to melt the crucible blank during a corresponding period of time at a corresponding position, and reaches a bottom polishing position after moving at least 3 times; the bottom polishing position is a lowest position that the graphite electrode reaches and enters an interior of the crucible blank, 300-550 mm away from a bottom of the crucible; at the bottom polishing position, the graphite electrode stays for a predetermined time to perform high-temperature polishing and volatile impurity removal to the bottom of the crucible;
after leaving from the bottom polishing position, the graphite electrode ascends again to a finishing position, the finishing position is +0.05-0.07 times the outer diameter of the crucible, at this position, high-temperature polishing and volatile impurity removal are conducted to an upper part of an inner wall of the quartz crucible.

2. The manufacturing method according to claim 1, wherein, during the entire melting process, the positioning of the graphite electrode comprises the starting position, a second position, a third position, a fourth position, a fifth position, the bottom polishing position and the finishing position, wherein from the starting position to the bottom polishing position is stepwise descending and staying for a period of time at each position.

3. The manufacturing method according to claim 2, wherein, the dwell time allocation for the graphite electrode at each position is as follows: a sum of the dwell time at the starting position, the second position, and the third position is 0.4-0.5 t, the dwell time at the fourth position is 0.1-0.2 t, the dwell time at the fifth position is 0.1 t, the dwell time at the bottom polishing position is 0.2-0.3 t, and the dwell time at the finishing position is 0.1 t; t is a total melting time of a target quartz crucible.

4. The manufacturing method according to claim 3, wherein, according to quartz crucibles with different specifications, the dwell time allocation for the graphite electrode at each position is as follows:
a quartz crucible with an outer diameter of 24 inches: the sum of the dwell time at the starting position, the second position and the third position is 0.4 t, the dwell time at the fourth position is 0.2 t, the dwell time at the fifth position is 0.1 t, the dwell time at the bottom polishing position is 0.2 t; the dwell time at the finishing position is 0.1 t; and the total melting time is 14-16 minutes;
a quartz crucible with an outer diameter of 26 inches: the sum of the dwell time at the starting position, the second position and the third position is 0.45 t, the dwell time at the fourth position is 0.15 t, the dwell time at the fifth position is 0.1 t, the dwell time at the bottom polishing position is 0.2 t; the dwell time at the finishing position is 0.1 t; and the total melting time is 17-19 minutes;
a quartz crucible with an outer diameter of 28 inches: the sum of the dwell time at the starting position, the second position and the third position is 0.45 t, the dwell time at the fourth position is 0.1 t, the dwell time at the fifth position is 0.1 t, the dwell time at the bottom polishing position is 0.25 t; the dwell time at the finishing position is 0.1 t; and the total melting time is 22-26 minutes;
a quartz crucible with an outer diameter of 32 inches: the sum of the dwell time at the starting position, the second position and the third position is 0.4 t, the dwell time at the fourth position is 0.1 t, the dwell time at the fifth position is 0.1 t, the dwell time at the bottom polishing position is 0.3 t; the dwell time at the finishing position is 0.1 t; and the total melting time is 28-32 minutes.

5. The manufacturing method according to claim 1, wherein, during graphite electrode positioning process, positioning accuracy of the graphite electrode at each position is ±5 mm.

6. The manufacturing method according to claim 1, wherein, during the entire melting process, vacuum pressure is controlled at −0.093 MPa˜−0.1 MPa; power of the graphite electrode is 500-2000 kW.

7. The manufacturing method according to claim 6, wherein, when melting a quartz crucible with an outer diameter of 24 inches, the power of the graphite electrode is 750-850 kW; when melting a quartz crucible with an outer diameter of 26 inches, the power of the graphite electrode is 850-950 kW; when melting a quartz crucible with an outer diameter of 28 inches, the power of the graphite electrode is 1000-1100 kW; when melting a quartz crucible with an outer diameter of 32 inches, the power of the graphite electrode is 1300-1400 kW.

8. The manufacturing method according to claim 1, wherein, during graphite electrode positioning process, at the end of melting at each position, the graphite electrode is subjected to air blowing for dust removal, and volatile matter deposited on a surface of the graphite electrode is blown away.

9. The manufacturing method according to claim 2, wherein, a height difference between the bottom polishing position and the fifth position is more than 100 mm.

10. A high-quality quartz crucible, wherein, the crucible is produced using the manufacturing method according to claim 1.
